(19) United States
(12) Patent Application Publication
(10) Pub. No.: US 2025/0096101 A1
(43) Pub. Date: Mar. 20, 2025

(54) CHIP-SUBSTRATE COMPOSITE SEMICONDUCTOR DEVICE

(71) Applicant: Infineon Technologies AG, Neubiberg (DE)

(72) Inventors: Carsten Joachim von Koblinski, Villach (AT); Tobias Polster, Finkenstein (AT)

(21) Appl. No.: 18/809,460

(22) Filed: Aug. 20, 2024

(30) Foreign Application Priority Data
Sep. 14, 2023 (DE) 102023124839.1

(51) Int. Cl. H01L 23/498; H01L 21/48; H01L 23/00; H01L 23/13; H01L 23/15

(52) U.S. Cl. CPC H01L 23/49838; H01L 21/4857; H01L 23/13; H01L 24/08; H01L 24/94; H01L 23/15; H01L 2224/08245; H01L 2224/94

(57) ABSTRACT

A semiconductor device includes a semiconductor chip having a front side and a backside. A first electrode is disposed on the front side of the semiconductor chip. An inorganic substrate includes a first side, a second side opposite the first side, and a first lateral side extending between the first side and the second side. A metal layer is disposed over the first side and the first lateral side of the inorganic substrate. The first electrode is bonded to the metal layer.

### TECHNICAL FIELD

This disclosure relates generally to the field of semiconductor devices, and in particular to the field of high-voltage semiconductor chips.

### BACKGROUND

When producing thin semiconductor chips, mechanical stability of the wafer, wafer-handling, chip-separation, chip-handling and further packaging processes become more difficult. Some of the known processes use reversible carrier systems to support the semiconductor wafer or the semiconductor chips singulated from the wafer during wafer processing or packaging. However, after removal of such reversible carrier systems, the semiconductor wafer or semiconductor chips no longer have sufficient mechanical support. Further, thick metal layers may bring high stress to the thin semiconductor wafer or semiconductor chips leading to warpage or bending of the semiconductor material as a result of CTE (coefficient of thermal expansion) mismatch.

### SUMMARY

According to an aspect of the disclosure a semiconductor device comprises a semiconductor chip having a front side and a backside, wherein a first electrode is disposed on the front side of the semiconductor chip. The semiconductor device comprises an inorganic substrate having a first side, a second side opposite the first side and a first lateral side extending between the first side and the second side. A metal layer is disposed over the first side and the first lateral side of the inorganic substrate. The first electrode is bonded to the metal layer.

According to an aspect of the disclosure a method of manufacturing a plurality of semiconductor devices comprises providing an inorganic substrate comprising a first side and a second side opposite the first side; forming a grid of trenches in the first side of the inorganic substrate, thereby defining a pattern of pedestals at the first side; forming a metal layer over the first side of the inorganic substrate, wherein the metal layer extends over pedestals and side walls of the trenches; attaching the semiconductor substrate to the inorganic substrate by bonding the plurality of first electrodes to the structured metal layer; thinning the semiconductor substrate to obtain a thinned semiconductor substrate; separating the thinned semiconductor substrate into a plurality of semiconductor chips; and separating the inorganic substrate into the plurality of semiconductor devices.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other and/or can be selectively omitted if not described to be necessarily required. Embodiments are depicted in the drawings and are exemplarily detailed in the description which follows.

FIG. 1 is a schematic cross-sectional view of an exemplary semiconductor device including a semiconductor chip and an inorganic substrate.

FIG. 2 is a schematic cross-sectional view of an exemplary semiconductor device including a semiconductor chip and an inorganic substrate, wherein the inorganic substrate includes a semiconductor substrate and an insulating layer covering the semiconductor substrate.

FIG. 3A is a schematic cross-sectional view of an example of a semiconductor device having a first electrode and a second electrode disposed on the front side of the semiconductor chip, wherein the metal layer is structured to connect to both electrodes.

FIG. 3B is a schematic cross-sectional view of an example of a semiconductor device having a first electrode and a second electrode disposed on the front side of the semiconductor chip, wherein the metal layer is structured to connect to the first electrode while the second electrode is connected to a vertical metal structure of a first type running through the inorganic substrate.

FIG. 3C is a schematic cross-sectional view of an example of a semiconductor device having a first electrode and a second electrode disposed on the front side of the semiconductor chip, wherein the metal layer is structured to connect to the first electrode while the second electrode is connected to a vertical metal structure of a second type running through the inorganic substrate.

FIG. 4 is a schematic cross-sectional view of an exemplary semiconductor device further including a device carrier.

FIG. 5 is a perspective top view on an exemplary inorganic substrate with a grid of trenches in the first side of the inorganic substrate, thereby defining a pattern of pedestals.

FIG. 6A is a cross-sectional view of an example of a trench in the first side of the inorganic substrate.

FIG. 6B is a cross-sectional view of another example of a trench in the first side of the inorganic substrate.

FIG. 7 is a perspective top view on the exemplary inorganic substrate of FIG. 5 after forming a metal layer over the first side of the inorganic substrate.

FIG. 8A is an enlarged portion of FIG. 7 illustrating a pedestal as viewed from one side of FIG. 7 after structuring the metal layer.

FIG. 8B is an enlarged portion of FIG. 7 illustrating a pedestal as viewed from the opposite side of FIG. 7 after structuring the metal layer.

FIG. 9A is a cross-sectional view of an example of a metal layer in the trench of the inorganic substrate.

FIG. 9B is a cross-sectional view of another example of a metal layer in the trench of the inorganic substrate.

FIG. 10 illustrates a stage of a process of manufacturing a semiconductor device before attaching a semiconductor substrate to the inorganic substrate.

FIG. 11 illustrates a stage of a process of manufacturing a semiconductor device after attaching the semiconductor substrate to the inorganic substrate.

FIG. 12 illustrates the stage of a process shown in FIG. 11, wherein the semiconductor substrate exemplarily includes a grid of pre-fabricated grooves filled with polymer material.

FIG. 13 illustrates the stage of a process shown in FIG. 11 or 12 after thinning the semiconductor substrate.

FIG. 14 illustrates a stage of a process of manufacturing a semiconductor device after separating the thinned semiconductor substrate into a plurality of semiconductor chips by an etching process.

FIG. 15 illustrates a stage of a process of manufacturing a semiconductor device after separating the thinned semiconductor substrate into a plurality of semiconductor chips by a laser cutting process.

FIG. 16 illustrates a stage of a process of manufacturing a semiconductor device after separating the inorganic substrate in a plurality of chip-substrate composite semiconductor devices.

FIG. 17 is a schematic side view of an exemplary semiconductor device including a leadframe as a device carrier.

### DETAILED DESCRIPTION

As used in this specification, the terms “electrically connected” or “connected” or similar terms are not meant to mean that the elements are directly contacted together; intervening elements may be provided between the “electrically connected” or “connected” elements, respectively. However, in accordance with the disclosure, the above-mentioned and similar terms may, optionally, also have the specific meaning that the elements are directly contacted together, i.e. that no intervening elements are provided between the “electrically connected” or “connected” elements, respectively.

Further, the words “over” or “beneath” with regard to a part, element or material layer formed or located or arranged “over” or “beneath” a surface may be used herein to mean that the part, element or material layer be located (e.g. placed, formed, arranged, deposited, etc.) “directly on” or “directly under”, e.g. in direct contact with, the implied surface. The word “over” or “beneath” used with regard to a part, element or material layer formed or located or arranged “over” or “beneath” a surface may, however, either be used herein to mean that the part, element or material layer be located (e.g. placed, formed, arranged, deposited, etc.) “indirectly on” or “indirectly under” the implied surface, with one or more additional parts, elements or layers being arranged between the implied surface and the part, element or material layer.

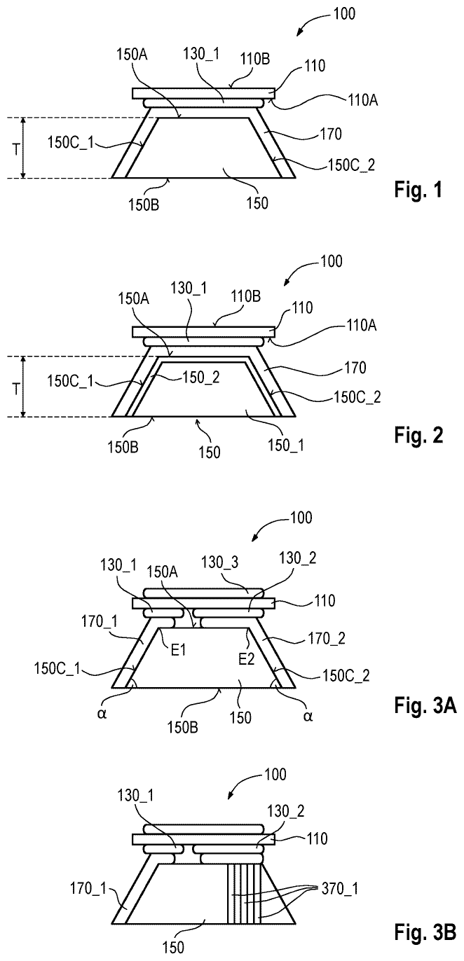

FIG. 1 illustrates a schematic cross-sectional view of an exemplary semiconductor device 100. The semiconductor device 100 includes a semiconductor chip 110. The semiconductor chip 110 has a front side 110A and a backside 110B. A first electrode 130_1 is disposed on the front side 110A of the semiconductor chip 110.

Further, the semiconductor device 100 includes an inorganic substrate 150. The inorganic substrate 150 includes a first side 150A, a second side 150B opposite the first side 150A and at least a first lateral side 150C_1. A metal layer 170 is disposed over the first side 150A and the first lateral side 150C_1 of the inorganic substrate 150.

The first electrode 130_1 of the semiconductor chip 110 is bonded to the metal layer 170. The inorganic substrate 150 may, e.g., have a thickness T measured between the first side 150A and the second side 150B of at least 50 μm.

Hence, the semiconductor device 100 is a semiconductor chip-inorganic substrate composite device. The inorganic substrate 150 provides mechanical stability to the semiconductor device 100, allowing the semiconductor device 100 to be handled and further processed in, e.g., packaging processes.

In one example, the inorganic substrate 150 may be a glass substrate. In other examples, it may be possible to use a semiconductor substrate (e.g. a Si-substrate) coated with an insulating layer (as shown in FIG. 2) for the inorganic substrate 150.

The surface of the inorganic substrate 150 at the first side 150A and at the first lateral side 150C_1 may be electrically insulating in order to avoid any short circuiting of the metal layer 170, if structured (as will be explained further below). For example, the inorganic substrate 150 may comprise or be made of an electrically insulating material or coated with an electrically insulating material.

The semiconductor chip 110 may have a (small) thickness of equal to or less than 30 μm or 20 μm or 15 μm or 10 μm, for example. Semiconductor chips of such thickness are also termed ultra-thin chips or “one digit chips” (if the thickness is below 10 μm) in the art. As will be described further below in more detail, it is also possible that the semiconductor chip 110 is formed of an epitaxial layer, which can be produced with such small thickness, for example.

The semiconductor chip 110 may, e.g., be a power chip. For example, the semiconductor chip 110 may be a power transistor chip or a power diode chip. In particular, load voltages of equal to or greater than, e.g., 50 V, 100 V, 200 V, 300 V, 400 V, 500 V, 600 V, 700 V, 800 V, 900 V or 1000 V may be applied to the semiconductor chip 110.

The metal layer 170 may, e.g., provide for high current flow. For example, the metal layer 170 may have a minimum thickness in a range between 5 and 100 μm, in particular 20 and 50 μm.

If the semiconductor device 100 is a power semiconductor device, the first electrode 130_1 may, e.g., be a load electrode of the power semiconductor device 100. However, as will be described further below, it is also possible to connect the metal layer 170 or structured parts of the metal layer 170 to one or more electrodes of the semiconductor chip 110 which are no load electrodes but, for example, control electrodes and/or sense electrodes (Kelvin electrodes), etc.

For example, if the semiconductor chip 110 includes an integrated power transistor, the semiconductor chip 110 may be configured as including one or more MISFETs (Metal Insulator Semiconductor Field Effect Transistors), MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors) or bipolar transistors.

The semiconductor chip 110 may, e.g., be made of any semiconductor material, e.g. Si, SiC, SiGe, GaAs, GaN, AlGaN, InGaAs, InAlAs, etc. In particular, Si or SiC power chips 110 are considered herein.

The semiconductor chip 110 is irreversibly attached to the inorganic substrate 150 by the bond connection between the first electrode 130_1 of the semiconductor chip 110 and the metal layer 170 disposed over the first side 150A of the inorganic substrate 150. For example, the bond connection may be a metal-to-metal direct bond connection or a eutectic bond connection.

For example, the first electrode 130_1 may comprise or be of copper or a copper alloy, and the metal layer 170 may comprise copper or be of copper or a copper alloy. A metal-to-metal direct bond connection may, in particular, be formed as a thermo-compression bond connection between these or other materials.

In other examples, the first electrode 130_1 and/or the metal layer 170 may be of other metal materials. They may, e.g., comprise or be of Au or an Au-based alloy. In these and other cases the bond connection may, e.g., be a eutectic bond connection.

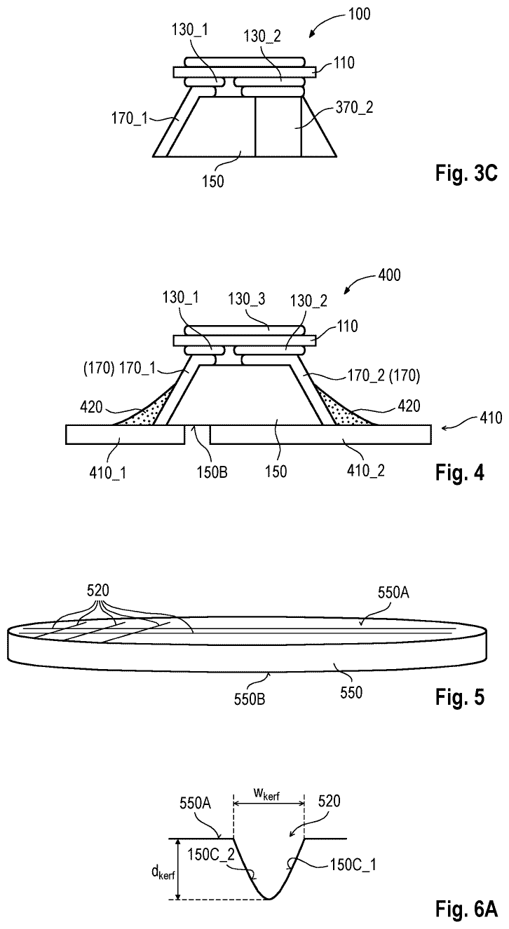

FIG. 3A illustrates an example of a semiconductor device 100. The semiconductor device 100 is similar to the semiconductor device 100 of FIG. 1, and reference is made to the above description for sake of brevity. The semiconductor device 100 of FIG. 3A distinguishes from the semiconductor device 100 of FIG. 1 in that a second electrode 130_2 is disposed on the front side 110A of the semiconductor chip 110.

Further, the metal layer 170 is structured to comprise a first continuous conducting path 170_1 extending over the first side 150A, the first lateral side 150C_1 and an edge E1 between the first side 150A and the first lateral side 150C_1. The structured metal layer 170 may further comprise a second continuous conducting path 170_2 extending over the first side 150A, the second lateral side 150C_2 and an edge E2 between the first side 150A and the second lateral side 150C_2. The second electrode 130_2 is bonded to the second continuous conducting path 170_2. The bond connection between the second electrode 130_2 and the second continuous conducting path 170_2 may be established the same way as described above for the bond connection between the first electrode 130_1 and the metal layer 170.

FIG. 3A further illustrates, by way of example, that a third electrode 130_3 of the semiconductor chip 110 may be disposed on the backside 110B of the semiconductor chip 110.

For example, if the semiconductor chip 110 is a transistor chip, the first electrode 130_1 may be a control electrode (e.g. gate electrode) or a sense electrode, the second electrode 130_2 may, e.g., be a source electrode or an emitter electrode and the third electrode 130_3 may, e.g., be a drain electrode or a collector electrode of the semiconductor chip 110. In other examples, when the semiconductor chip 110 is a horizontal device, all transistor electrodes as mentioned above may be disposed on the front side 110A of the semiconductor chip 110.

Further, the semiconductor chip 110 may, e.g., be a device which has a single electrode (e.g., first electrode 130_1) at the front side 110A of the semiconductor chip 110 and a single electrode (e.g., third electrode 130_3) on the backside 110B of the semiconductor chip 110. In this case, the semiconductor chip 110 may, e.g., be a (power) diode. A semiconductor device including such semiconductor chip 110 may be designed as shown in FIG. 1 or 2, wherein in these Figures the electrode on the backside 110B of the semiconductor chip 110 (corresponding to the third electrode 130_3 of FIG. 3A) is not depicted.

Moreover, it is possible that the semiconductor chip 110 has a single electrode (corresponding to the first electrode 130_1) disposed on the front side 110A (as shown in FIGS. 1 and 2) and a plurality of electrodes (not shown in FIGS. 1 and 2) disposed on the backside 110B of the semiconductor chip 110.

FIG. 2 is a schematic cross-sectional view of an exemplary semiconductor device 100 which is similar to the semiconductor device 100 of FIG. 1 except that the inorganic substrate 150 includes a semiconductor substrate 150_1 and an insulating layer 150_2 covering the semiconductor substrate 150_1. The semiconductor substrate 150_1 may, e.g., be of silicon and the insulating layer 150_2 may be a hard passivation layer such as, e.g., silicon oxide and/or silicon nitride.

FIGS. 3B and 3C illustrate further examples of a semiconductor device 100. Referring to FIG. 3B, the inorganic substrate 150 may comprise a vertical metal structure running through the inorganic substrate 150 from the first side 150A to the second side 150B. The second electrode 130_2 is bonded to the vertical metal structure.

In FIG. 3B the vertical metal structure may comprise or be formed of plated metal pillars 370_1. To this end, recesses or through-holes may be formed in the inorganic substrate 150. The recesses or through-holes may then be filled by plating with an appropriate material, e.g. Cu. The lateral dimension (e.g., diameter) of each plated metal pillar 370_1 may, e.g., be equal to or greater than or less than 10 μm or 15 μm or 20 μm or 25 μm.

Referring to FIG. 3C, the vertical metal structure may, e.g., be formed by a bulk metal inlay 370_2. The bulk metal inlay 370_2 may be formed by wet-chemical etching a through-hole in the inorganic substrate 150 and by subsequently filling the through-hole with an appropriate metal, e.g. Cu. The bulk metal inlay 370_2 may be a single metal structure having a lateral dimension which may be similar to the lateral dimension of the second electrode 130_2. For example, the lateral dimension of the second electrode 130_2 may, e.g., be equal to or greater than or less than 100 μm or 500 μm or 1 mm or 2 mm.

In all examples, the inorganic substrate 150 may have a thickness T as described above with reference to FIG. 1. The thickness T of the inorganic substrate 150 of the semiconductor device 100 shown in FIG. 3B may preferably be between 150 and 200 μm. On the other hand, the thickness of the inorganic substrate 150 of the semiconductor device 100 of FIG. 3C may preferably be between 50 and 100 μm, for example.

In the examples shown in FIGS. 3B and 3C, the second electrode 130_2 (e.g., source or emitter electrode) of the semiconductor chip 110 may be contacted by a through-inorganic substrate contact, while the first electrode 130_1 (e.g., gate contact) may be contacted by a continuous (first) conducting path 170_1 running over a lateral side face (e.g., first lateral side 150C_1) of the inorganic substrate 150.

In all examples the inorganic substrate 150 represents an irreversible (i.e., permanent) pedestal used to support the fragile semiconductor chip 110 so as to provide the required mechanical stability and robustness to the semiconductor device 100.

FIG. 4 illustrates an example of a semiconductor device 400 which includes one of the semiconductor devices 100 as described above and a device carrier 410 on which the semiconductor device 100 is mounted. While in FIG. 4 the semiconductor device 100 mounted on the device carrier 410 is, e.g., shown to be the semiconductor device 100 illustrated in FIG. 3A, all other examples of the semiconductor devices 100 as described above may be used.

The device carrier 410 may be any suitable carrier, e.g. may comprise a leadframe or an application board or a ceramic-based carrier or a printed circuit board (PCB), etc. A bonding material 420 connects a portion of the metal layer 170 (e.g., a portion of the first continuous conducting path 170_1 and/or a portion of the second continuous conducting path 170_2) extending over the first lateral side 150C_1 and/or over the second lateral side 150C_2 with the device carrier 410 or an electrical conductor (not shown) provided by the device carrier 410. For example, the first continuous conducting path 170_1 may be connected by the bonding material 420 to a first part 410_1 of the device carrier 410 (e.g., a leadframe) and the second continuous conducting path 170_2 may be connected by the bonding material 420 to a second part 410_2 of the device carrier 410.

The bonding material 420 may, e.g., be solder or an electrically conductive adhesive (glue). Solder may be preferred in some examples as it wets the contacting surfaces of the device carrier 410 and the metal layer 170 automatically during the process of mounting the semiconductor device 100 on the device carrier 410.

In some of the examples the lateral side (e.g., first lateral side 150C_1 and/or second lateral side 150C_2) may be oblique with respect to the second side 150B at an angle α of less than 90° or 80° or 70°. The inclined geometry of the lateral sides of the inorganic substrate 150 may facilitate the mounting process. Further, structuring of the metal layer 170 at the side faces (first side 150A and/or second side 150B) of the inorganic substrate 150 may be much easier.

FIGS. 5 to 16 illustrate stages of an exemplary method of manufacturing a plurality of semiconductor devices 100.

Referring to FIG. 5, an inorganic substrate 550 is provided. The inorganic substrate 550 may, e.g., be a wafer. The inorganic substrate 550 is the precursor of the inorganic substrate 150 described before, and may therefore be of one of the materials mentioned above with respect to the inorganic substrate 150.

The inorganic substrate 550 has a first side 550A and a second side 550B opposite the first side 550A. A grid of trenches 520 is formed in the first side 550A of the inorganic substrate 550. By forming the grid of trenches 520 a pattern of pedestals is defined at the first side 550A of the inorganic substrate 550.

The grid of trenches 520 may, e.g., be lattice-shaped. The trenches 520 may, e.g., be mechanically cut (e.g., sawed) into the inorganic substrate 550 (e.g., a glass wafer or a silicon wafer coated by an insulating layer). The size of the tile-shaped regions at the first side 550A of the inorganic substrate 550 defined by the grid of trenches 520 may correspond to the size of the semiconductor chips 110, which are intended to be attached thereto.

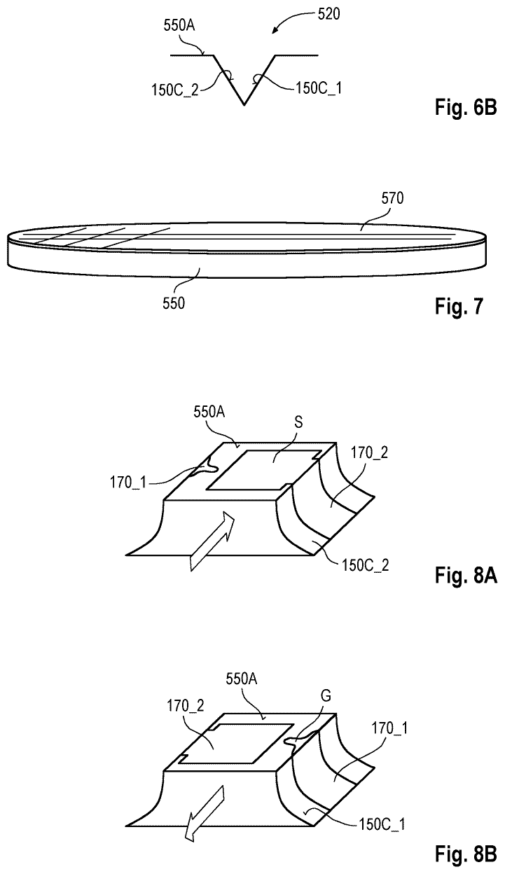

The trenches 520 may vary in shape and/or depth. Referring to FIGS. 6A and 6B, the trenches 520 may have a depth d_{kerf} and a width W_{kerf}. The depth d_{kerf} may be selected so that the intended thickness TM of the inorganic substrates 150 (see FIG. 1) can be achieved by, e.g., back-thinning, as will be described further below. The width W_{kerf} may be chosen so as to allow metal deposition in the desired thickness TM of the metal layer 170 and in-trench structuring of the metal layer 170.

For example, the depth d_{kerf} may, e.g., be in a range between 50 and 250 μm, in particular 100 and 200 μm. The width W_{kerf} of the trenches 520 may be chosen in a range between 100 μm and 200 μm, for example. The greater the desired thickness TM of the metal layer 170, the greater may be the width W_{kerf} of the trenches 520.

The trenches 520 may have a tapering shape in the downward direction. For example, the tapering shape may be rounded (FIG. 6A) or acute, e.g. V-shaped (e.g. FIG. 6B). A rounded shape (FIG. 6A) may, e.g., be parabolic.

Referring to FIG. 7, a metal layer 570 is formed over the first side 550A of the inorganic substrate 550. The metal layer 570 extends over the top of the pedestals and sidewalls 150C_1, 150C_2 of the trenches 520.

Metallization of the inorganic substrate 550 may comprise depositing a single metal layer or a metal layer stack on the first side 550A of the inorganic substrate 550. For example, the inorganic substrate 550 may be metallized by a first thin adhesive layer, which adheres well to the material of the inorganic substrate 550 (e.g. glass or an insulating layer coating a silicon substrate). For example, the adhesive layer (not shown) may comprise or be of Ti/Cu or Ag.

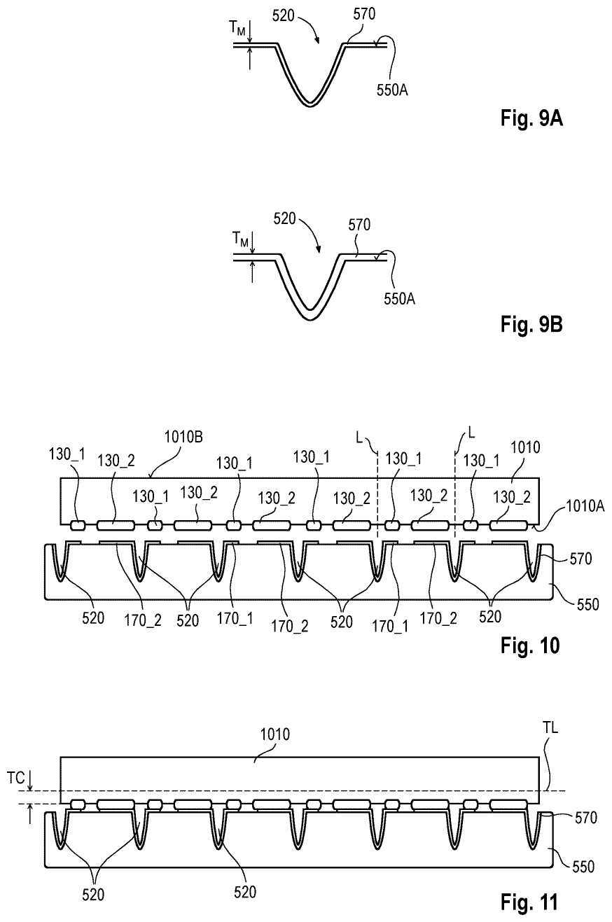

Subsequently, forming of the metal layer 570 may include metal plating (e.g., galvanic plating) to the desired thickness TM. The thickness TM may depend on whether a load current (e.g., source current) or a control or sense signal is to be conducted by the metal layer 570 (FIGS. 9A, 9B). The thickness TM may be in a range between 5 μm and 30 μm, in particular between 8 μm and 20 μm, for example.

The metal layer 570 may be structured, for example. Structuring may be carried out by lithography in regions over the pedestals and/or at sidewalls of the trenches 520. The sidewalls of the trenches 520 correspond to the first and second lateral sides 150C_1 and 150C_2 of the inorganic substrate 150.

Referring to FIGS. 8A and 8B, the metal layer 570 may be structured to comprise a first continuous conducting path 170_1 extending over the first side 550A of the inorganic substrate 550 and over a sidewall of the trench 520 (corresponding to the first lateral side 150C_1 of the inorganic substrate 150), and/or the metal layer 570 may be structured to comprise a second continuous conducting path 170_2 extending over the first side 550A of the inorganic substrate 550 and over a sidewall of the trench 520 (corresponding to the second lateral side 150C_2 of the inorganic substrate 150). For example, the first continuous conducting path 170_1 may connect to a gate G electrode (or, more generally, the first electrode 130_1) of the semiconductor chip 110 and/or the second continuous conducting path 170_2 may connect to a source(S) electrode (or, more generally, to the second electrode 130_2) of the semiconductor chip 110. The first and second continuous conducting path 170_1 and 170_2 are thus formed on opposite sidewalls of a trench 520 as indicated by the arrows.

It has been found that in-trench structuring of the metal layer 570 can be carried out by classical optical lithography. A spray coater may be used to apply the photoresist onto the first side 550A of the inorganic substrate 550. The structuring of the metal layer 570 on the top surface of the pedestals and in the trenches 520 may be carried out simultaneously. More specifically, the photoresist may be exposed simultaneously on the top surface of the pedestals and in the trenches 520. The focus of the optical lithography tool may be placed on the top surface of the pedestals. Further lithography steps, such as developing the photoresist (photoresist etching), may also be carried out simultaneously on the top surface of the pedestals and in the trenches 520.

Referring to FIG. 10, a semiconductor substrate 1010 is provided. The semiconductor substrate 1010 includes a front side 1010A and a backside 1010B. A plurality of first electrodes 130_1 and (optionally) a plurality of second electrodes 130_2 are disposed on the front side 1010A of the semiconductor substrate 1010. The size of a semiconductor chip 110 to be cut out of the semiconductor substrate 1010 is indicated by lines L. The inorganic substrate 550 and the semiconductor substrate 1010 are positioned relative to each other so as lines L align with the bottoms of the trenches 520.

Referring to FIG. 11, the semiconductor substrate 1010 is then attached to the inorganic substrate 550 by bonding the plurality of first electrodes 130_1 and (optionally) the plurality of second electrodes 130_2 to the structured metal layer 570. Bonding may include metal-to-metal direct bonding, in particular thermo-compression bonding. In other examples, eutectic bonding may be used.

Thermo-compression bonding includes heating and applying a relatively high pressure to the semiconductor substrate 1010 and the inorganic substrate 550. Copper, as an electrode material and a metal layer material, is especially suited for direct metal-to-metal bonding. Further, a high planarity within a range of +5 μm TTV (total thickness variation) may be obtained by direct metal-to-metal bonding. A high semiconductor substrate planarity may be important in view of the following semiconductor substrate thinning process.

FIG. 11 indicates a thinning line TL. The semiconductor substrate 1010 is thinned from its backside down to the thinning line TL to obtain a thinned semiconductor substrate 1010T. The thinned semiconductor substrate 1010T may have a thickness TC of the semiconductor chips 110.

In some examples, the semiconductor substrate 1010 may include an etch stop layer. The etch stop layer may be indicated by the thinning line TL. In other words, the etch stop layer may be arranged such that the semiconductor substrate (e.g. wafer) 1010 is thinned by an etching process down to the thinning line TL, where the etching process stops at the etch stop layer.

The etch stop layer (at TL) allows to precisely set a desired thickness TC of the semiconductor chips 110, which is greatly independent from the TTV of the inorganic substrate 550. Without etch stop layer, the thickness TC of the semiconductor chips 110 would directly depend on the TTV of the inorganic substrate 550. For example, if the inorganic substrate 550 has a TTV of +5 μm and the intended thickness TC of the semiconductor chips 110 is 10 μm, the thickness TC of the semiconductor chips 110 would vary at least between 5 μm and 15 μm in a process in which the semiconductor substrate 1010 were thinned by backside grinding. The etch stop layer, on the other hand, allows to compensate for the TTV of the inorganic substrate 550, thus making the thinning process (much more) independent from the TTV of the inorganic substrate 550.

For example, the semiconductor substrate 1010 may be a silicon-on-insulator (SOI) substrate. In this case, the etch stop layer may be provided by the buried oxide (BOX) layer in the SOI substrate 1010. The base silicon of the SOI substrate 1010 is thinned, and the thin top silicon layer above the BOX layer of a precisely defined thickness TC is used as the thinned semiconductor substrate 1010T.

In other examples, the thinned semiconductor substrate 1010T may be formed of an epitaxial layer deposited on a substrate suitable for epitaxial growth. This substrate may be a low-cost substrate, which does not need to be made of silicon, for example. This approach has the advantage that no expensive wafer material needs to be thinned away. In addition, with an epitaxial layer, the thickness TC of the thinned semiconductor substrate 1010T can be controlled with high precision. That way, the semiconductor chip may be formed by a solely epitaxial layer, for example.

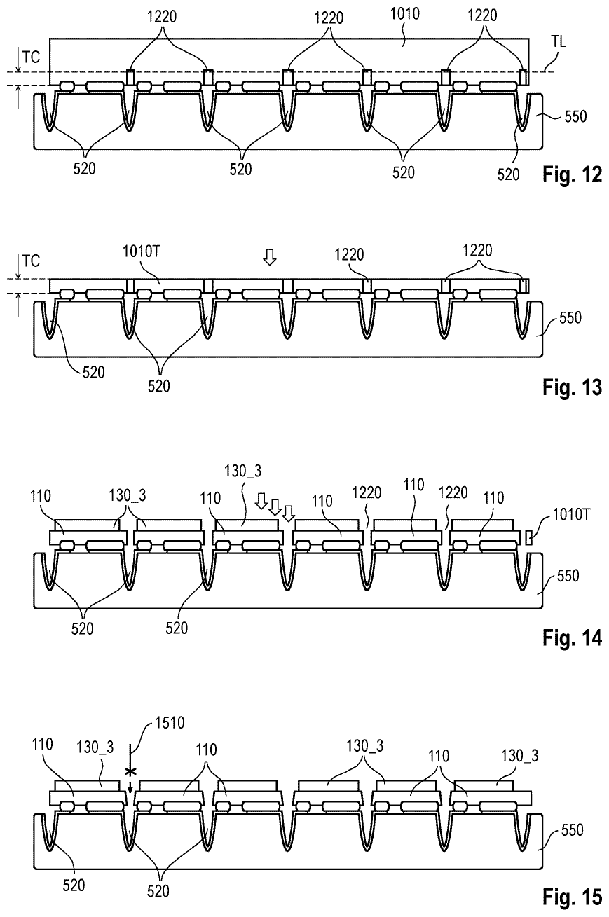

FIG. 12 illustrates a variation of the example of FIG. 11. In the example of FIG. 12 the semiconductor substrate 1010 includes pre-fabricated grooves 1220 (trenches) aligned with lines L. The pre-fabricated grooves 1220 may be filled with a polymer material, e.g. an epoxy-based material. The pre-fabricated grooves 1220 are formed in the front side 1010A of the semiconductor substrate 1010 and may have a depth equal to or greater than TC.

After thinning, the polymer material in the pre-fabricated grooves 1220 is exposed at the backside of the thinned semiconductor substrate 1010T, as illustrated in FIG. 13. The integrity of the thinned semiconductor substrate 1010T is maintained by the polymer material. If no pre-fabricated grooves 1220 are provided in the thinned semiconductor substrate 1010T, the integrity of the thinned semiconductor substrate 1010T is maintained by the substrate as such.

Subsequently, the thinned semiconductor substrate 1010T may be subjected to semiconductor processing. For example, one or more ion implant processes may be performed to the backside surface of the thinned semiconductor substrate 1010T obtained by the thinning process. In particular, ion implanting may be used to generate highly doped regions adjacent to the backside surface obtained by thinning. In addition, a metal layer may be formed over the backside surface of the thinned semiconductor substrate 1010T. The metal layer may then be structured to provide third electrodes 130_3, for example.

Referring to FIG. 14, the thinned semiconductor substrate 1010T is then separated into a plurality of semiconductor chips 110. Chip separation may be carried out by laser cutting, for example. In other examples, when the thinned semiconductor substrate 1010T is provided with a polymer-filled groove pattern, the thinned semiconductor substrate 1010T may be separated by etching the polymer material from the pre-fabricated grooves 1220. For example, a plasma etching process (indicated by arrows) may be used.

FIG. 15 illustrates separating the thinned semiconductor substrate 1010T by laser cutting. To this end, a laser beam 1510 is directed onto the thinned semiconductor substrate 1010T in alignment with the grid of trenches 520 in the inorganic substrate 550.

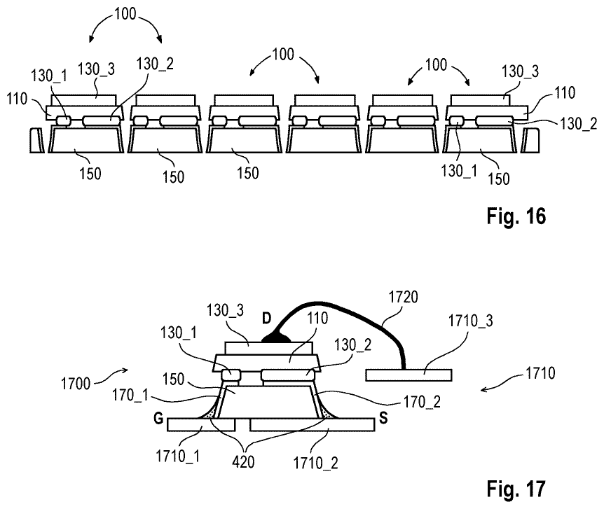

After the singulation of the thinned semiconductor substrate 1010T into semiconductor chips 110, the inorganic substrate 550 may be separated to obtain a plurality of semiconductor devices 100 (i.e., chip-substrate composite devices), for example (see FIG. 16). To this end, the arrangement shown in FIG. 14 or 15 may be flipped and placed on a temporary carrier (not shown). The inorganic substrate 550 may then be separated into a plurality of individual inorganic substrates 150 as described before. For example, the inorganic substrate 550 may be thinned until the metal layer 170 is separated at the bottom of the trenches 520. As shown in FIG. 16, this results in separated semiconductor devices 100 with continuous conducting paths 170_1, 170_2 connected to chip electrodes 130_1, 130_2 at opposite sides of the semiconductor chips 110.

FIG. 17 illustrates an exemplary semiconductor device 1700 including a leadframe 1710 as a device carrier. In the example shown, the third electrode 130_3 may be the drain (D) electrode of the semiconductor chip 110. Similar to the device carrier 410, the leadframe 1710 may include a first part 1710_1 bonded to the first continuous conducting path 170_2 and a second part 1710_2 bonded to the second continuous conducting path 170_2. Further, the leadframe 1710 may include a third part 1710_3 connected to the third electrode 130_3 by a wire bond connection 1720, a clip connection or a ribbon connection, for example.

The following examples pertain to further aspects of the disclosure:

Example 1 is a semiconductor device including a semiconductor chip having a front side and a backside, wherein a first electrode is disposed on the front side of the semiconductor chip. The semiconductor device comprises an inorganic substrate having a first side, a second side opposite the first side and a first lateral side extending between the first side and the second side. A metal layer is disposed over the first side and the first lateral side of the inorganic substrate. The first electrode is bonded to the metal layer.

In Example 2, the subject matter of Example 1 can optionally further include a device carrier on which the inorganic substrate is mounted with the second side facing the device carrier; and a bonding material configured to electrically connect a portion of the metal layer extending over the first lateral side with the device carrier or an electrical conductor provided by the device carrier.

In Example 3, the subject matter of Example 1 or 2 can optionally include wherein the metal layer is structured to comprise a first continuous conducting path extending over the first side, the first lateral side and an edge between the first side and the first lateral side.

In Example 4, the subject matter of Example 3 can optionally include wherein a second electrode is disposed on the front side of the semiconductor chip; the inorganic substrate further comprises a second lateral side extending between the first side and the second side; and the metal layer is structured to comprise a second continuous conducting path extending over the first side, the second lateral side and an edge between the first side and the second lateral side, wherein the second electrode is bonded to the second continuous conducting path.

In Example 5, the subject matter of Example 3 can optionally include a second electrode is disposed on the front side of the semiconductor chip; and the inorganic substrate comprises a vertical metal structure running through the inorganic substrate from the first side to the second side, the second electrode being bonded to the vertical metal structure.

In Example 6, the subject matter of any of the preceding Examples can optionally include wherein the metal layer has a minimum thickness in a range between 5 and 100 μm, in particular 20 and 50 μm.

In Example 7, the subject matter of any of the preceding Examples can optionally include wherein a bond connection between the first electrode and the metal layer is a metal-to-metal direct bond connection, in particular a thermo-compression bond connection, or a eutectic bond connection.

In Example 8, the subject matter of any of the preceding Examples can optionally include wherein the inorganic substrate is a glass substrate.

In Example 9, the subject matter of any of the preceding Examples can optionally include wherein the inorganic substrate is a semiconductor substrate coated with an insulating layer.

In Example 10, the subject matter of any of the preceding Examples can optionally include wherein the first lateral side is oblique with respect to the second side at an angle of less than 90°.

In Example 11, the subject matter of any of the preceding Examples can optionally include wherein the inorganic substrate has a thickness measured between the first side and the second side of at least 50 μm.

In Example 12, the subject matter of any of the preceding Examples can optionally include wherein the semiconductor chip has a thickness of equal to or less than 20 μm or 15 μm or 10 μm.

In Example 13, the subject matter of any of the preceding Examples can optionally include wherein the semiconductor chip is formed by an epitaxial layer.

In Example 14, the subject matter of any of the preceding Examples can optionally include wherein the semiconductor chip is a power chip.

Example 15 is a method of manufacturing a plurality of semiconductor devices comprises providing an inorganic substrate comprising a first side and a second side opposite the first side; forming a grid of trenches in the first side of the inorganic substrate, thereby defining a pattern of pedestals at the first side; forming a metal layer over the first side of the inorganic substrate, wherein the metal layer extends over pedestals and side walls of the trenches; attaching the semiconductor substrate to the inorganic substrate by bonding the plurality of first electrodes to the structured metal layer; thinning the semiconductor substrate to obtain a thinned semiconductor substrate; separating the thinned semiconductor substrate into a plurality of semiconductor chips; and separating the inorganic substrate into the plurality of semiconductor devices.

In Example 16, the subject matter of Example 15 can optionally include wherein forming the metal layer comprises metal plating to form the metal layer with a thickness in a range between 5 μm and 30 μm, in particular between 8 μm and 20 μm.

In Example 17, the subject matter of Example 15 or 16 can optionally include structuring the metal layer by lithography in regions over the pedestals and/or at side walls of the trenches.

In Example 18, the subject matter of any of Examples 15 to 17 can optionally include wherein bonding the plurality of electrodes to the structured metal layer comprises metal-to-metal direct bonding, in particular thermo-compression bonding, or eutectic bonding.

In Example 19, the subject matter of any of Examples 15 to 18 can optionally include wherein thinning the semiconductor substrate comprises obtaining a thinned semiconductor substrate having a thickness of equal to or less than 20 μm or 15 μm or 10 μm.

In Example 20, the subject matter of Example 19 can optionally include wherein thinning comprises etching the semiconductor substrate to the etch stop layer.

In Example 21, the subject matter of Example 19 or 20 can optionally include wherein performing one or more ion implant processes to a surface of the thinned semiconductor substrate obtained by thinning and/or forming a structured metal layer over a surface of the thinned semiconductor substrate obtained by thinning.

In Example 22, the subject matter of any of Examples 15 to 21 can optionally include wherein separating the thinned semiconductor substrate into a plurality of semiconductor chips comprises etching polymer material from pre-fabricated grooves in the thinned semiconductor substrate, or laser cutting of the thinned semiconductor substrate.

In Example 23, the subject matter of any of Examples 15 to 22 can optionally include wherein separating the thinned semiconductor substrate into a plurality of semiconductor chips and separating the inorganic substrate into the plurality of semiconductor devices are performed one after another and by different separating processes.

In Example 24, the subject matter of any of Examples 15 to 23 can optionally include wherein separating the inorganic substrate into the plurality of semiconductor devices comprises thinning the inorganic substrate until reaching the trenches.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor chip comprising a front side and a backside, wherein a first electrode is disposed on the front side of the semiconductor chip;
an inorganic substrate comprising a first side, a second side opposite the first side, and a first lateral side extending between the first side and the second side; and
a metal layer disposed over the first side and the first lateral side of the inorganic substrate,
wherein the first electrode is bonded to the metal layer.

2. The semiconductor device of claim 1, further comprising:
a device carrier on which the inorganic substrate is mounted with the second side facing the device carrier; and
a bonding material configured to electrically connect a portion of the metal layer extending over the first lateral side with the device carrier or an electrical conductor provided by the device carrier.

3. The semiconductor device of claim 1, wherein the metal layer is structured to comprise a first continuous conducting path extending over the first side, the first lateral side, and an edge between the first side and the first lateral side.

4. The semiconductor device of claim 3, wherein:
a second electrode is disposed on the front side of the semiconductor chip;
the inorganic substrate further comprises a second lateral side extending between the first side and the second side; and
the metal layer is structured to comprise a second continuous conducting path extending over the first side, the second lateral side, and an edge between the first side and the second lateral side, wherein the second electrode is bonded to the second continuous conducting path.

5. The semiconductor device of claim 3, wherein:
a second electrode is disposed on the front side of the semiconductor chip; and
the inorganic substrate comprises a vertical metal structure running through the inorganic substrate from the first side to the second side, the second electrode being bonded to the vertical metal structure.

6. The semiconductor device of claim 1, wherein the metal layer has a minimum thickness in a range between 5 and 100 μm.

7. The semiconductor device of claim 1, wherein a bond connection between the first electrode and the metal layer is a metal-to-metal direct bond connection or a eutectic bond connection.

8. The semiconductor device of claim 1, wherein the inorganic substrate is a glass substrate.

9. The semiconductor device of claim 1, wherein the inorganic substrate is a semiconductor substrate coated with an insulating layer.

10. The semiconductor device of claim 1, wherein the first lateral side is oblique with respect to the second side at an angle of less than 90°.

11. The semiconductor device of claim 1, wherein the inorganic substrate has a thickness measured between the first side and the second side of at least 50 μm.

12. The semiconductor device of claim 1, wherein the semiconductor chip has a thickness of equal to or less than 20 μm or 15 μm or 10 μm.

13. The semiconductor device of claim 1, wherein the semiconductor chip is formed by an epitaxial layer.

14. The semiconductor device of claim 1, wherein the semiconductor chip is a power chip.

15. A method of manufacturing a plurality of semiconductor devices, the method comprising:
providing a semiconductor substrate comprising a front side and a backside, wherein a plurality of first electrodes is disposed on the front side of the semiconductor substrate;
providing an inorganic substrate comprising a first side and a second side opposite the first side;
forming a grid of trenches in the first side of the inorganic substrate, the grid of trenches defining a pattern of pedestals at the first side;
forming a metal layer over the first side of the inorganic substrate, wherein the metal layer extends over pedestals and side walls of the trenches;
attaching the semiconductor substrate to the inorganic substrate by bonding the plurality of first electrodes to the structured metal layer;
thinning the semiconductor substrate to obtain a thinned semiconductor substrate;
separating the thinned semiconductor substrate into a plurality of semiconductor chips; and
separating the inorganic substrate into the plurality of semiconductor devices.

16. The method of claim 15, wherein forming the metal layer comprises metal plating to form the metal layer with a thickness in a range between 5 μm and 30 μm.

17. The method of claim 15, further comprising:
structuring the metal layer by lithography in regions over the pedestals and/or at side walls of the trenches.

18. The method of claim 15, wherein bonding the plurality of electrodes to the structured metal layer comprises metal-to-metal direct bonding or eutectic bonding.

19. The method of claim 15, wherein thinning the semiconductor substrate comprises obtaining a thinned semiconductor substrate having a thickness of equal to or less than 20 μm or 15 μm or 10 μm.

20. The method of claim 19, wherein the semiconductor substrate comprises an etch stop layer, wherein the thinning comprises etching the semiconductor substrate to the etch stop layer.

21. The method of claim 19, further comprising:
performing one or more ion implant processes to a surface of the thinned semiconductor substrate obtained by the thinning; and/or
forming a structured metal layer over a surface of the thinned semiconductor substrate obtained by the thinning.

22. The method of claim 15, wherein separating the thinned semiconductor substrate into a plurality of semiconductor chips comprises:
etching polymer material from pre-fabricated grooves in the thinned semiconductor substrate; or
laser cutting of the thinned semiconductor substrate.

23. The method of claim 15, wherein separating the thinned semiconductor substrate into a plurality of semiconductor chips and separating the inorganic substrate into the plurality of semiconductor devices are performed one after another and by different separating processes.

24. The method of claim 15, wherein separating the inorganic substrate into the plurality of semiconductor devices comprises:
thinning the inorganic substrate until reaching the trenches.
